(19) United States
(12) Patent Application Publication
(10) Pub. No.: US 2026/0277040 A1
(43) Pub. Date: Sep. 17, 2026

(54) DISPLAY SUBSTRATE AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Zhengdong ZHANG, Beijing (CN); Pengcheng ZANG, Beijing (CN); Bo WU, Beijing (CN); Ting LI, Beijing (CN); Changyi WANG, Beijing (CN)

(21) Appl. No.: 19/168,231

(22) PCT Filed: Apr. 23, 2024
(86) PCT No.: PCT/CN2024/089375

§ 371 Date: Sep. 23, 2025

(30) Foreign Application Priority Data
Apr. 26, 2023 (CN) 202310465274.7

(51) Int. Cl. G02F 1/133; G02F 1/1335; G02F 1/1343; H10D 86/40

(52) U.S. Cl. CPC G02F 1/13306; G02F 1/133553; G02F 1/13439; H10D 86/441; H10D 86/451

(57) ABSTRACT

The display substrate includes: a base substrate, each sub-pixel region including a reflection region and a transmissive region; and pixel driving units. Each pixel driving unit includes: a driving circuit layer including a transistor driving circuit; an organic layer on the side of the driving circuit layer facing away from the base substrate and provided with a first connection hole, the orthographic projection of the first connection hole on the base substrate at least partially overlapping the transmissive region; and a reflective electrode on the side of the organic layer facing away from the driving circuit layer, the orthographic projection of the reflective electrode on the base substrate at least covers the reflection region, the reflective electrode is provided with a first light-transmitting hole arranged opposite to the first connection hole, and the orthographic projection of the first light-transmitting hole on the base substrate overlaps the transmissive region.

### CROSS-REFERENCE OF RELATED APPLICATIONS

The present application is a national phase entry under 35 U.S.C § 371 of International Application No. PCT/CN2024/089375, filed on Apr. 23, 2024, which claims the priority from Chinese Patent Application No. 202310465274.7, filed with the China National Intellectual Property Administration on Apr. 26, 2023 and entitled “Display Substrate and Display Device”, which is hereby incorporated by reference in its entirety.

### TECHNICAL FIELD

The present disclosure relates to the technical field of display device, and in particular to a display substrate and a display device.

### BACKGROUND

The outdoor environment is usually bright during the day. In order to better display the image, traditional outdoor display devices need to have very high brightness, which will result in high power consumption of the display device. If a reflective display device is used outdoors, when the ambient light brightness is very high, the product power consumption can be greatly reduced. However, when the ambient brightness decreases or it is at night, a clear display function cannot be achieved.

### SUMMARY

The present application provides a display substrate and a display device. The display substrate can increase the area of the reflective electrode that can reflect external light, thereby greatly improving the reflectivity of the display panel in a high-brightness environment.

To achieve the above objectives, the present application provides the following technical solutions.

A display substrate, including:
a base substrate including a plurality of sub-pixel regions, each of the plurality of sub-pixel regions including a reflective region and a transmissive region;
a plurality of pixel driving units, arranged on a side of the base substrate, where orthographic projections of the plurality of pixel driving units on the base substrate are located in the plurality of sub-pixel regions in a one-to-one correspondence;
where each of the plurality of pixel driving units includes:
a driving circuit layer, arranged on the base substrate and including a transistor driving circuit;
an organic layer, arranged on a side of the driving circuit layer facing away from the base substrate, where the organic layer is provided with a first connection hole, an orthographic projection of the first connection hole on the base substrate at least partially overlaps with the transmissive region;
a reflective electrode, arranged on a side of the organic layer facing away from the driving circuit layer, where an orthographic projection of the reflective electrode on the base substrate at least covers the reflective region, the reflective electrode is provided with a first light-transmitting hole corresponding to the first connection hole, an orthographic projection of the first light-transmitting hole on the base substrate coincides with the transmissive region.

In some embodiments, the pixel driving unit further includes an inorganic layer and a connection wire;
the inorganic layer is arranged between the organic layer and the driving circuit layer, the inorganic layer is provided with a second connection hole, and an orthographic projection of the second connection hole on the base substrate at least partially overlaps with the orthographic projection of the first connection hole on the base substrate;
the connection wire is arranged between the inorganic layer and the base substrate, a first end of the connection wire is electrically connected to the transistor driving circuit, a second end of the connection wire is exposed from the second connection hole and electrically connected to the reflective electrode.

In some embodiments, the second end of the connection wire is exposed from the first connection hole; and the reflective electrode is connected to the second end of the connection wire in the first connection hole.

In some embodiments, the pixel driving unit further includes: a transparent electrode arranged between the driving circuit layer and the reflective electrode;
an orthographic projection of the transparent electrode on the base substrate at least covers the orthographic projection of the first connection hole on the base substrate;
the reflective electrode is connected to the second end of the connection wire through the transparent electrode.

In some embodiments, the transparent electrode is arranged between the organic layer and the reflective electrode.

In some embodiments, an orthographic projection of the connection wire on the base substrate overlaps with an edge of the orthographic projection of the first connection hole on the base substrate.

In some embodiments, in a radial direction of the first connection hole, only one side of the orthographic projection of the first connection hole on the base substrate overlaps with the orthographic projection of the connection wire on the base substrate.

In some embodiments, in a radial direction of the first connection hole, a width of an overlapping region between the orthographic projection of the first connection hole on the base substrate and the orthographic projection of the connection wire on the base substrate is greater than 0 microns and less than or equal to 3 microns.

In some embodiments, the pixel driving unit further includes a transparent electrode, a region of the transparent electrode corresponding to the first connection hole is recessed into the first connection hole to form a concave portion;
the orthographic projection of the first light-transmitting hole on the base substrate coincides with an orthographic projection of the concave portion on the base substrate.

In some embodiments, the pixel driving unit further includes an inorganic layer and a transparent electrode;
the inorganic layer is arranged between the organic layer and the driving circuit layer, the inorganic layer is provided with a third connection hole, and an orthographic projection of the third connection hole on the base substrate does not overlap with the orthographic projection of the first connection hole on the base substrate;
the transparent electrode is arranged between the inorganic layer and the organic layer, the transparent electrode is electrically connected to the transistor driving circuit through the third connection hole, and the transparent electrode is electrically connected to the reflective electrode through the first connection hole.

In some embodiments, the driving circuit layer is provided with a second light-transmitting hole, the inorganic layer is provided with a third light-transmitting hole;
an orthographic projection of the second light-transmitting hole on the base substrate covers an orthographic projection of the third light-transmitting hole on the base substrate;
the orthographic projection of the third light-transmitting hole on the base substrate covers the orthographic projection of the first light-transmitting hole on the base substrate;
a region of the transparent electrode corresponding to the third light-transmitting hole is recessed into the second light-transmitting hole and the third light-transmitting hole; and
the reflective electrode is electrically connected to the transparent electrode through the first connection hole.

In some embodiments, the driving circuit layer includes a gate metal layer, a gate insulating layer, a semiconductor layer, and a source-drain metal layer sequentially arranged on the base substrate;
the transistor driving circuit includes: a switching transistor and a capacitor electrode;
the switching transistor includes: a gate electrode arranged in the gate metal layer, an active layer arranged in the semiconductor layer, and a first electrode and a second electrode arranged in the source-drain metal layer;
the first electrode and the second electrode are electrically connected to the active layer, the first electrode is electrically connected to the reflective electrode, and the capacitor electrode is arranged between the source-drain metal layer and the base substrate, and the capacitor electrode is arranged opposite to the first electrode.

In some embodiments, the driving circuit layer further includes a pad layer on a same layer as the gate electrode;
the pad layer is provided with a fourth light-transmitting hole, and an orthographic projection of the fourth light-transmitting hole on the base substrate covers the orthographic projection of the first connection hole on the base substrate.

In some embodiments, the organic layer is provided with a scattering portion on a side facing the reflective electrode; and
an orthographic projection of the scattering portion on the base substrate covers the reflective region.

In some embodiments, the orthographic projection of the reflective electrode on the base substrate covers an orthographic projection of the transistor driving circuit on the base substrate.

The present application further provides a display device, including any one of the display substrates provided in the above embodiments.

Embodiments of the present application provide a display substrate and a display device. The display substrate can be used in a liquid crystal display panel, including a base substrate and a plurality of pixel driving units on the base substrate. The base substrate includes a plurality of sub-pixel regions; each of the sub-pixel regions is divided into a reflective region and a transmissive region. The plurality of pixel driving units are located in the plurality of sub-pixel regions in a one-to-one correspondence. The pixel driving unit includes a driving circuit layer, an organic layer, and a reflective electrode, which are sequentially arranged on the base substrate. The organic layer is provided with a first connection hole, the orthographic projection of the first connection hole on the base substrate at least partially overlaps with the transmissive region, the orthographic projection of the reflective electrode on the base substrate at least covers the reflective region, the reflective electrode is provided with a first light-transmitting hole corresponding to the first connection hole, the orthographic projection of the first light-transmitting hole on the base substrate coincides with the transmissive region. Compared with the related art, the deep hole in the reflective region of the organic layer can be eliminated, and only the first connection hole corresponding to the transmissive region is provided on the organic layer. This can increase the area in the reflective region where the reflective electrode can reflect external light, thereby greatly improving the reflectivity of the display panel in a high-brightness environment.

### BRIEF DESCRIPTION OF FIGURES

FIG. 1 is a schematic structural diagram of a display device according to some embodiments of the present application.

FIG. 2 is a schematic structural diagram of a pixel driving unit according to some embodiments of the present application.

FIG. 3 is a schematic structural diagram of a base substrate according to some embodiments of the present application.

FIG. 4 is a schematic structural diagram of a pixel driving unit according to some embodiments of the present application.

FIG. 5 is another schematic structural diagram of a pixel driving unit according to some embodiments of the present application.

FIG. 6 is another schematic structural diagram of a pixel driving unit according to some embodiments of the present application.

FIG. 7 is another schematic structural diagram of a pixel driving unit according to some embodiments of the present application.

FIG. 8 is another schematic structural diagram of a pixel driving unit according to some embodiments of the present application.

FIG. 9 is another schematic structural diagram of a pixel driving unit according to some embodiments of the present application.

### ICONS

1—base substrate; 2—driving circuit layer; 21—gate metal layer; 22—gate insulating layer; 23—semiconductor layer; 24—source-drain metal layer; 210—switching transistor; 211—gate electrode; 212—active layer; 213—first electrode; 214—second electrode; 220—capacitor electrode; 230—connection wire; 240—pad layer; 241—fourth light-transmitting hole; 250—light-transmitting hole; 260—second light-transmitting hole; 3—organic layer; 31—first connection hole; 4—reflective electrode; 41—first light-transmitting hole; 5—transparent electrode; 51—concave portion; 6—inorganic layer; 61—second connection hole; 62—third connection hole; 63—third light-transmitting hole.

### DETAILED DESCRIPTION

The technical solutions in embodiments of the present application will be clearly and completely described below in conjunction with the drawings in embodiments of the present application. Obviously, the described embodiments are only part of the embodiments of the present application, not all of the embodiments. Based on embodiments in the present application, all other embodiments obtained by ordinary technicians in this field without making any creative work shall fall within the scope of protection of the present application.

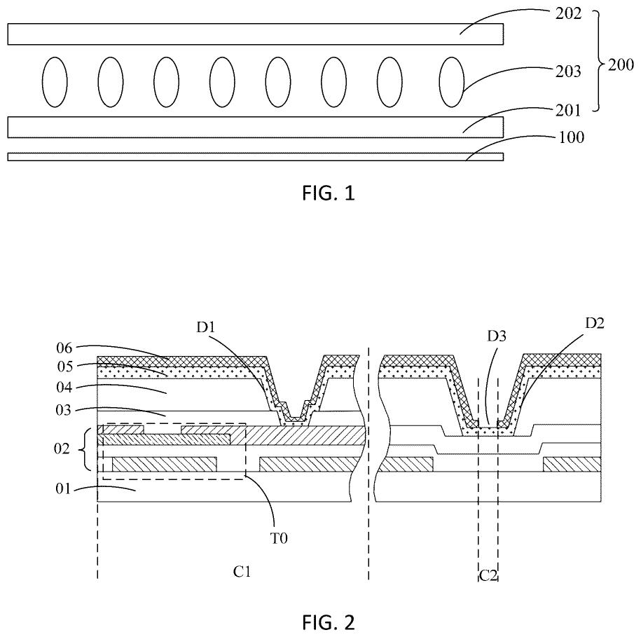

In order to solve the problem of high power consumption of outdoor display devices, the related technology provides a liquid crystal display device. As shown in FIG. 1, the liquid crystal display device includes a backlight module 100 and a liquid crystal display panel 200 arranged on the light-emitting side of the backlight module 100. The liquid crystal display panel 200 can include an array substrate 201 and a color filter substrate 202 arranged opposite to each other and a liquid crystal layer 203 arranged between the array substrate and the color filter substrate. The array substrate 201 can include a base substrate and a plurality of pixel driving units arranged on the base substrate, where the base substrate includes a display region and a non-display region arranged around the display region. The display region can include a plurality of sub-pixel regions. The orthographic projections of the plurality of pixel driving units on the base substrate are located in the plurality of sub-pixel regions in a one-to-one correspondence. Each sub-pixel region can include a reflective region C1 and a transmissive region C2. Specifically, as shown in FIG. 2, each pixel driving unit can include a driving circuit layer 02, an inorganic layer 03, an organic layer 04, a transparent electrode 05 and a reflective electrode 06 arranged in sequence on the base substrate 01. The driving circuit layer 02 is provided with the switching transistor T0. The organic layer 04 and the inorganic layer 03 have a first via-hole D1 in the reflective region C1. The transparent electrode 06 is connected to the source electrode of the switching transistor T0 through the first via-hole D1. The organic layer 04 is further provided with a second via-hole D2. The region of the reflective electrode 06 corresponding to the second via-hole D2 is provided with a light-transmitting hole D3. The orthographic projection of the light-transmitting hole D3 on the base substrate coincides with the transmissive region C2.

The above-mentioned liquid crystal display device is a semi-transmissive and semi-reflective display device, which can be used outdoors. When the outdoor environment is a high-brightness environment, the liquid crystal display panel can be used as a reflective display panel, and can display images without the need for a backlight module to provide light source, thereby saving energy consumption. When the outdoor environment is a low-brightness environment, the liquid crystal display device can use the backlight module to provide light source for the liquid crystal display panel to realize image display. Specifically, when the outside world is a high-brightness environment, the high-brightness ambient light from the outside can be incident on the liquid crystal display panel from the side where the color film substrate is located, and then reflected by the reflective electrode on the array substrate. The pixel driving units can adjust the rotation direction of the liquid crystal in the liquid crystal layer in different sub-pixel regions, and the emission state of the reflected light can be adjusted through the liquid crystal layer, thereby realizing image display. When the outside world is a low-brightness environment, the ambient light is weak and not enough to be reflected to illuminate the screen, and the light source can be provided by the backlight module. The light emitted by the backlight module enters the interior of the LCD display panel through the light-transmitting hole. The pixel driving units can adjust the rotation direction of the liquid crystal in the liquid crystal layer in different sub-pixel regions, and the emission state of the incident light emitting from the liquid crystal display panel can be adjusted through the liquid crystal layer, thereby realizing image display.

In the array substrate shown in FIG. 2, the switching transistor T0 in the driving circuit layer 02 can be controlled to provide a driving voltage to the transparent electrode 05 and the reflective electrode 06 to adjust the rotation direction of the liquid crystal in the liquid crystal layer. The reflective electrode 05 and the transparent electrode 06 are electrically connected to the source electrode of the switching transistor T0 through the first via-hole D1 in the reflective region C1. The thickness of the organic layer 04 forming the first via-hole D1 is generally thick, about 2 microns, which results in a deep depth of the first via-hole D1. Light cannot be diffusely reflected in the region where the first via-hole D1 is located. In order to achieve the connection between the electrode and the drain electrode of the switching transistor, the diameter of the first via-hole D1 also needs to be increased accordingly, about 6 microns. Therefore, it will result in a large region where the reflection region C1 cannot form diffuse reflection, which greatly affects the reflectivity of the liquid crystal display panel.

In order to solve the above technical problems, embodiments of the present application provide a display substrate, including:
a base substrate 1, as shown in FIG. 3, includes a plurality of sub-pixel regions C, each sub-pixel region includes a reflective region C1 and a transmissive region C2;
a plurality of pixel driving units, arranged on a side of the base substrate 1, and the orthographic projections of the plurality of pixel driving units on the base substrate 1 are located in the plurality of sub-pixel regions C in a one-to-one correspondence.

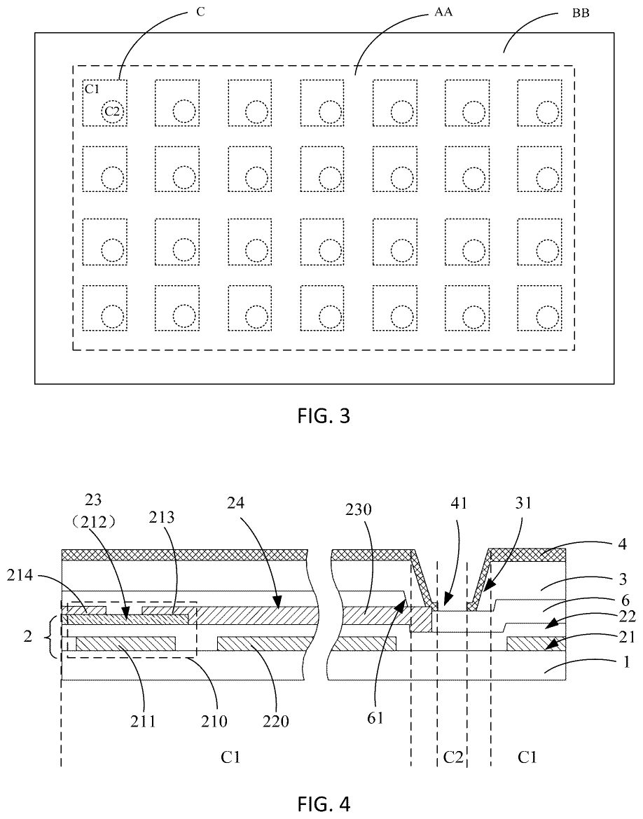

As shown in FIG. 4, each pixel driving unit includes:
a driving circuit layer 2 on the base substrate 1, and the driving circuit layer 2 includes a transistor driving circuit;
an organic layer 3 on a side of the driving circuit layer 2 facing away from the base substrate 1; the organic layer 3 is provided with a first connection hole 31, and an orthographic projection of the first connection hole 31 on the base substrate 1 at least partially overlaps with the transmissive region C2;
a reflective electrode 4 on a side of the organic layer 3 facing away from the driving circuit layer 2, an orthographic projection of the reflective electrode 4 on the base substrate 1 at least covers the reflective region C1; the reflective electrode 4 is provided with a first light-transmitting hole 41 corresponding to the first connection hole 31, an orthographic projection of the first light-transmitting hole 41 on the base substrate 1 coincides with the transmissive region C2.

The display substrate provided in embodiments of the present application can be applied to a liquid crystal display panel and includes a base substrate 1 and a plurality of pixel driving units on the base substrate 1. The base substrate 1 includes a plurality of sub-pixel regions C, each sub-pixel region C is divided into a reflective region C1 and a transmissive region C2. The plurality of pixel driving units are located in the plurality of sub-pixel regions C in a one-to-one correspondence. The pixel driving units include a driving circuit layer 2, an organic layer 3, and a reflective electrode 4, which are sequentially arranged on the base substrate 1. The organic layer 3 is provided with a first connection hole 31; the orthographic projection of the first connection hole 31 on the base substrate 1 at least partially overlaps with the transmissive region C2. The orthographic projection of the reflective electrode 4 on the base substrate 1 at least covers the reflective region C1. The reflective electrode 4 is provided with a first light-transmitting hole corresponding to the first connection hole 31. Compared with the related art, the deep hole in the reflective region of the organic layer can be eliminated, and only the first connection hole corresponding to the transmissive region is provided on the organic layer. This can increase the area of the reflective electrode in the reflective region that can reflect external light, thereby greatly improving the reflectivity of the display panel in a high-brightness environment.

In order to improve the reflectivity of the display panel, as shown in FIG. 4, the reflective region C1 can be the region in the sub-pixel region C except the region corresponding to the first connection hole 31, and the area of the transmissive region C2 is limited by the opening area size of the first light-transmitting hole 41. The opening shape of the first light-transmitting hole 41 can be circular, square, etc., which is not limited here and depends on the situation. In some embodiments, the areas of the reflective region C1 and the transmissive region C2 in each sub-pixel region C can generally be determined according to the product purpose and user usage scenario. For example, if the above-mentioned display substrate is used in a semi-transmissive and semi-reflective display device of a law enforcement instrument or a charging pile, the transmissive region C2 can be set smaller and closer to the edge of the sub-pixel region C. This can ensure the transmissive aperture ratio of the display substrate while improving the reflection efficiency.

In some embodiments, as shown in FIG. 4, the driving circuit layer 2 in the above-mentioned pixel driving unit can include a gate metal layer 21, a gate insulating layer 22, a semiconductor layer 23 and a source-drain metal layer 24 arranged in sequence on the base substrate 1. The transistor driving circuit can include a switching transistor 210 and a capacitor electrode 220. The switching transistor 210 can include a gate electrode 211 arranged in the gate metal layer 21, an active layer 212 arranged in the semiconductor layer 23, and a first electrode 213 and a second electrode 214 arranged in the source-drain metal layer 24. The first electrode 213 and the second electrode 214 are electrically connected to the active layer 212, and the first electrode 213 is electrically connected to the reflective electrode 4. The capacitor electrode 220 is arranged between the source-drain metal layer 24 and the base substrate 1 and is arranged opposite to the first electrode 213. For example, the first electrode 213 and the second electrode 214 can be a source electrode and a drain electrode, respectively. The capacitor electrode 220 can be arranged in the gate metal layer 21. The transistor driving circuit can control the voltage applied to the reflective electrode 4 by adjusting the state of the switching transistor 210, thereby conveniently controlling the rotation direction of the liquid crystal in the liquid crystal layer of the liquid crystal display panel.

In some embodiments, the orthographic projection of the reflective electrode 4 on the base substrate 1 can cover the orthographic projection of the transistor driving circuit on the base substrate 1, so that the transistor driving circuit is arranged below the reflective electrode 4, which can prevent the transistor driving circuit from affecting the transmittance of the transmissive region C2 of the display substrate to the light emitted by the backlight module, thereby improving the transmittance of the transmissive region C2. The material of the reflective electrode 4 can be metal Al, MoAl or Ag.

In some embodiments, the organic layer 3 can be made of an organic insulating material such as resin. A scattering portion can be provided on the side of the organic layer 3 facing the reflective electrode 4. The orthographic projection of the scattering portion on the base substrate 1 covers the reflective region C1. The scattering portion can be a diffuse reflective concave-convex topography formed on the side of the organic layer 3 facing the reflective electrode 4. This allows the reflective electrode 4 above the organic layer 3 to also have a diffuse reflective concave-convex topography in the reflective region C1; thereby ensuring that diffuse reflection is formed when external ambient light is irradiated on the reflective electrode 4.

In some embodiments of the present application, as shown in FIGS. 4 to 7, the pixel driving unit can further include an inorganic layer 6 and a connection wire 230; where the inorganic layer 6 is arranged between the organic layer 3 and the driving circuit layer 2, and the inorganic layer 6 is provided with a second connection hole 61, and the orthographic projection of the second connection hole 61 on the base substrate at least partially overlaps with the orthographic projection of the first connection hole 31 on the base substrate 1; the connection wire 230 is arranged between the inorganic layer 6 and the base substrate 1, and the first end of the connection wire 230 is electrically connected to the transistor driving circuit, and the second end of the connection wire 230 is exposed from the second connection hole 61 to electrically connected to the reflective electrode 4.

In the above embodiments, the transistor driving circuit is electrically connected to the reflective electrode 4 through the connection wire 230 between the inorganic layer 6 and the base substrate 1, eliminating the need to provide a deep hole in the reflective region C1 in the organic layer 3. This increases the area of the reflective electrode 4 reflecting external light, thereby significantly improving the reflectivity of the display panel in a high-brightness environment. In some embodiments, the orthographic projection of the connection wire 230 on the base substrate 1 cannot overlap or only partially overlap with the orthographic projection of the first light-transmitting hole 41 on the base substrate 1, thereby avoiding affecting the light transmissive effect at the first light-transmitting hole 41 and ensuring the transmittance of the display substrate to the light emitted by the backlight module.

The inorganic layer 6 can be made of an inorganic insulating material.

In some embodiments, the first end of the connection wire 230 can be electrically connected to the first electrode 213 of the switching transistor 210 in the transistor driving circuit, thereby achieving electrical connection between the transistor driving circuit and the transparent electrode 5.

Among them, the above-mentioned connection wire 230 can be prepared in the same layer as any metal layer in the driving circuit layer. For example, the above-mentioned connection wire 230 can be located in the source-drain metal layer 24, and prepared in the same layer as the first electrode 213 and the second electrode 214, which can simplify the manufacturing process, as shown in FIGS. 4 to 7. In some embodiments, the connection wire 230 can also be prepared in a different layer from the first electrode 213 and the second electrode 214. In some embodiments, the connection wire 230 can also be prepared in a separate layer. In this case, the material of the connection wire 230 can be a transparent metal material, which can avoid affecting the transmittance of the display substrate. The specific structure and material of the connection wire 230 are not limited here and are determined according to actual conditions.

In some embodiments, as shown in FIG. 4, the second end of the connection wire 230 is exposed from the first connection hole 31, and the reflective electrode 4 can be directly electrically connected to the second end of the connection wire 230 in the first connection hole 31, and electrical conduction is directly carried out between the reflective electrode 4 and the transistor driving circuit through the connection wire 230.

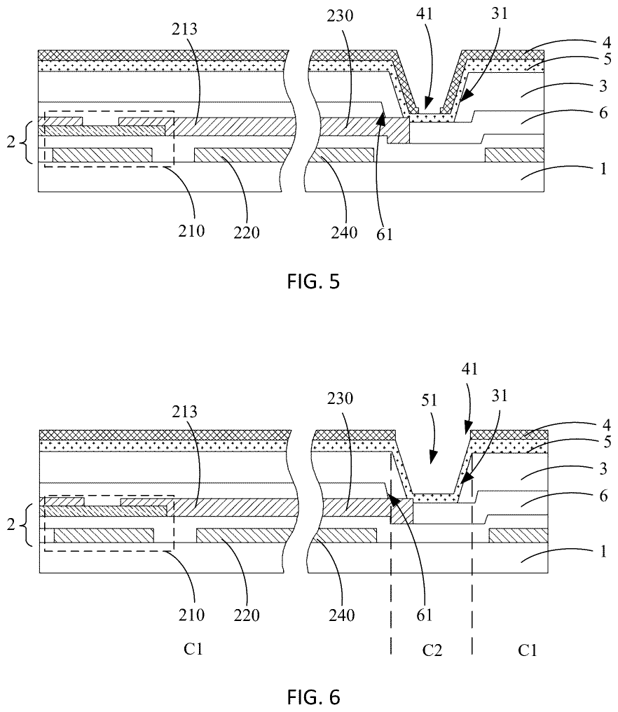

In some embodiments, as shown in FIGS. 5 to 7, the above-mentioned pixel driving unit can further include a transparent electrode 5 arranged between the driving circuit layer 2 and the reflective electrode 4, the orthographic projection of the transparent electrode 5 on the base substrate 1 at least covers the orthographic projection of the first connection hole 31 on the base substrate 1, the reflective electrode 4 is connected to the second end of the connection wire 230 through the transparent electrode 5, and can be electrically conductive through the transparent electrode 5 and the connection wire 230 to achieve electrical connection between the reflective electrode 4 and the transistor driving circuit. The transparent electrode 5 is provided with little effect on the light-transmitting effect at the first light-transmitting hole 41, thereby ensuring the transmittance of the display panel. The material of the transparent electrode 5 can be indium tin oxide, etc., which can be determined according to actual conditions and is not limited here.

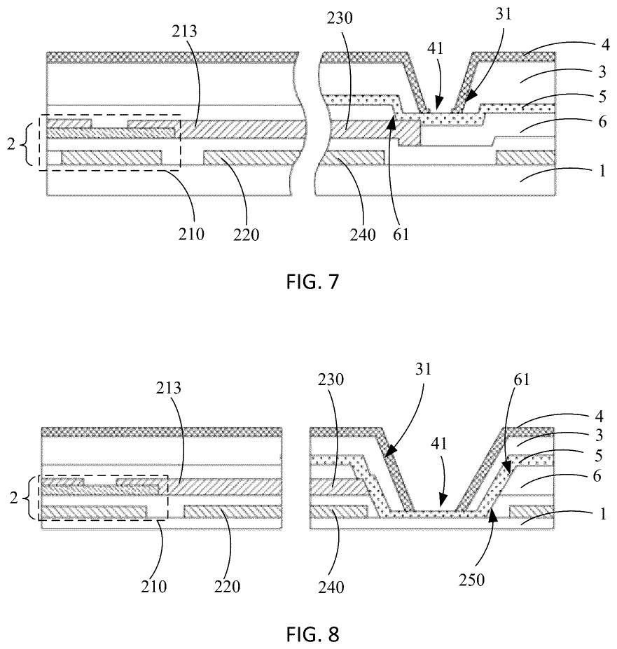

In some embodiments, the transparent electrode 5 can be arranged between the organic layer 3 and the reflective electrode 4, as shown in FIGS. 5 and 6. The orthographic projection of the transparent electrode 5 on the base substrate 1 can cover the orthographic projection of the reflective electrode 4 on the base substrate 1, which can facilitate the electrical connection between the reflective electrode 4 and the transparent electrode 5 and the production of the reflective electrode 4. In some embodiments, the transparent electrode 5 can be arranged between the inorganic layer 6 and the organic layer 3, as shown in FIGS. 7 and 8. There is no limitation here and it can be determined according to actual conditions.

In the above embodiments, when the reflective electrode 4 is directly electrically connected to the transistor driving circuit through the connection wire 230, as shown in FIG. 4, or when the transparent electrode 5 is arranged between the organic layer 3 and the reflective electrode 4, as shown in FIG. 5, the orthographic projection of the connection wire 230 on the base substrate 1 overlaps with the edge of the orthographic projection of the first connection hole 31 on the base substrate 1, and the connection wire 230 is electrically connected to the reflective electrode 4 or the transparent electrode 5 through the first connection hole 31. There is no need to form a deep hole in the portion of the organic layer 3 located in the reflective region C1. The electrical connection between the transistor driving circuit and the transparent electrode 5 can be achieved by extending the connection wire 230 to the edge of the first connection hole 31.

In some embodiments, as shown in FIGS. 4, 5 and 6, in the radial direction of the first connection hole 31, only one side of the orthographic projection of the first connection hole 31 on the base substrate 1 overlaps with the orthographic projection of the connection wire 230 on the base substrate 1. In this structure, only the end of the connection wire 230 is exposed from one side edge of the first connection hole 31, and the reflective electrode 4 or the transparent electrode 5 overlaps the connection wire 230 at the edge of the first connection hole 31 to achieve electrical connection, and can reduce the influence of the connection wire 230 on the transmittance of the display substrate.

In some embodiments, in the radial direction of the first connection hole 31, the width of the region between the orthographic projection of the first connection hole 31 on the base substrate 1 and the orthographic projection of the connection wire 230 on the base substrate 1 can be greater than 0 microns and less than or equal to 3 microns, which can ensure that the connection wire 230 is well overlapped in the first connection hole 31 and the transmittance of the display substrate can be guaranteed.

In some embodiments, in order to ensure a more reliable connection between the connection wire 230 and the reflective electrode 4 or the transparent electrode 5, the second end of the connection wire 230 can also be provided with a connection hole, and the orthographic projection of the connection hole on the base substrate 1 is located within the orthographic projection of the first connection hole 31 on the base substrate 1, so that the reflective electrode 4 or the transparent electrode 5 can be connected to the connection wire 230 at the surrounding edge of the first connection hole 31.

In the above embodiments, as shown in FIG. 6, when the transparent electrode 5 is arranged between the organic layer 3 and the reflective electrode 4, the region of the transparent electrode 5 corresponding to the first connection hole 31 is recessed into the first connection hole 31 to form a concave portion 51; the orthographic projection of the first light-transmitting hole 41 on the base substrate 1 and the orthographic projection of the concave portion 51 on the base substrate 1 can coincide with each other, so that the reflective electrode 4 is only overlapped at the edge of the concave portion 51 to achieve electrical connection between the reflective electrode 4 and the transparent electrode 5. This structure not only ensure the reflectivity of the display panel in the reflective region C1, but also increase the area of the light-transmitting area C2, thereby greatly improving the transmittance of the display substrate in the light-transmitting region C2.

In some embodiments of the present application, the above-mentioned driving circuit layer 2 can further have a light-transmitting hole 250, the orthographic projection of the light-transmitting hole 250 on the base substrate 1 covers the orthographic projection of the second connection hole 61 on the base substrate 1, and the orthographic projection of the second connection hole 61 on the base substrate covers the orthographic projection of the first connection hole 61 on the base substrate. At this time, the second end of the connection wire can be exposed from the side wall of the second connection hole, as shown in FIG. 8. By removing the inorganic layer 6 and the gate insulation layer 22 in the region corresponding to the first light-transmitting hole 41, the transmittance of the display substrate can be improved.

In some embodiments, the center lines of the first connection hole 31 and the first light-transmitting hole 41 can coincide with each other, thereby ensuring the transmittance of the display substrate in the transmissive region C2.

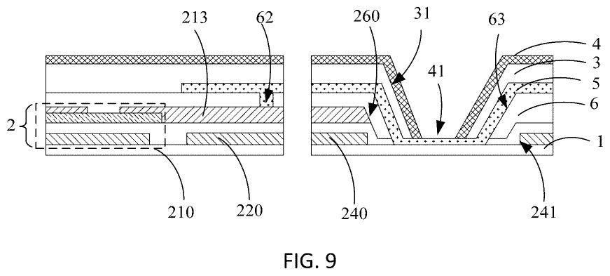

In some embodiments of the present application, the reflective electrode 4 and the transistor driving circuit can also be electrically connected only through the transparent electrode 5. As shown in FIG. 9, the inorganic layer 6 can have a third connection hole 62, and the orthographic projection of the third connection hole 62 on the base substrate 1 does not overlap with the orthographic projection of the first connection hole 61 on the base substrate 1. The transparent electrode 5 is arranged between the inorganic layer 6 and the organic layer 3. The transparent electrode 5 is electrically connected to the transistor driving circuit through the third connection hole 62. The transparent electrode 5 is electrically connected to the reflective electrode 4 through the first connection hole 31. The transparent electrode 5 on the base substrate 1 can cover the orthographic projection of the first connection hole 61 on the base substrate. In FIG. 9, the transparent electrode 5 is electrically connected to the transistor driving circuit arranged on the side of the inorganic layer 6 facing away from the organic layer 3 without passing through the organic layer 3. Thereby, a third connection hole 62 can be directly provided on the inorganic layer 6 to realize the connection between the transparent electrode 5 and the transistor driving circuit. The structure is simple and easy to manufacture.

In some embodiments, when the transparent electrode 5 is connected to the transistor driving circuit through the third connection hole 62, it can be set as shown in FIG. 9, the driving circuit layer 2 is provided with a second light-transmitting hole 260, the inorganic layer 6 is provided with a third light-transmitting hole 63, the orthographic projection of the second light-transmitting hole 260 on the base substrate 1 covers the orthographic projection of the third light-transmitting hole 63 on the base substrate 1, and the orthographic projection of the third light-transmitting hole 63 on the base substrate 1 covers the orthographic projection of the first light-transmitting hole 41 on the base substrate 1; the region of the transparent electrode 5 corresponding to the third light-transmitting hole 63 is recessed into the second light-transmitting hole 260 and the third light-transmitting hole 63, and the reflective electrode 4 is electrically connected to the transparent electrode 5 through the first connection hole 31. The presence of the inorganic layer 6 and the driving circuit layer 2 in the region corresponding to the first light-transmitting hole 31 will affect the transmittance to a certain extent. The production of the second light-transmitting hole 260 and the third light-transmitting hole 63 can remove the inorganic layer 6 and the gate insulation layer 22 in the corresponding region, which can maximize the transmittance of the display substrate.

In some embodiments, the center lines of the first light-transmitting hole 41, the second light-transmitting hole 260, the third light-transmitting hole 63 and the first connection hole 31 can be the same center line, which can better ensure the transmittance of the display substrate in the transmissive region C2.

In some embodiments, as shown in FIGS. 4 to 9, the above-mentioned driving circuit layer 2 can further include a pad layer 240 on the same layer as the gate electrode 211, and the pad layer 240 is provided with a fourth light-transmitting hole 241. The orthographic projection of the fourth light-transmitting hole 241 on the base substrate 1 covers the orthographic projection of the first connection hole 31 on the base substrate 1. The position of the fourth light-transmitting hole 241 on the pad layer 240 can be used to define a region for setting holes such as the first connection hole 31 and the first light-transmitting hole 41, thereby facilitating the production of the display substrate. Here, the pad layer 240 can be electrically connected to the capacitor electrode 220 prepared on the same layer to achieve functional reuse.

In some embodiments of the present application, as shown in FIG. 3, the base substrate 1 can include a display region AA and a non-display region BB surrounding the display region AA. The display region AA is provided with a plurality of sub-pixel regions C. Each sub-pixel region C includes a reflective region C1 and a transmissive region C2. The specific steps of manufacturing the display substrate shown in FIG. 6 on the base substrate 1 can include the following operations.
Step S101: depositing a gate metal layer on a base substrate, and forming a pattern of the gate metal layer using a mask process, where the pattern can include a gate electrode, a gate line, a capacitor electrode, a pad layer located in a display region, and a bonding terminal located in a non-display region.
Step S102: depositing a gate insulating layer and a semiconductor layer on the gate metal layer, and forming an active layer pattern through the semiconductor layer using a mask process.
Step S103: depositing a source-drain metal layer on the active layer, and forming a pattern of the source-drain metal layer using a masking process, where the pattern can include a source electrode, a drain electrode, connection wires, a data line located in the display region, and a bonding terminal located in the non-display region.
Step S104: depositing an inorganic layer on the source-drain metal layer, and forming a second connection hole in the region of the inorganic layer corresponding to the transmissive region using a mask process to expose the end of the connection wire.
Step S105: forming an organic layer on the inorganic layer, forming a first connection hole in the region of the organic layer corresponding to the transmissive region using a masking process to expose the end of the connection wire, removing the organic layer in the non-display region, and forming a diffuse reflective concave-convex topography in the region corresponding to the reflective region on the side of the organic layer facing away from the base substrate.
Step S106: depositing a transparent electrode layer on the organic layer, and forming a transparent electrode pattern or other transfer line pattern using a mask process.
Step S107: forming a reflective layer on the transparent electrode layer, and forming a reflective electrode pattern through a mask process.

The present application further provides a display device, including any one of the display substrates provided in the above embodiments.

In some embodiments, the display device can be a liquid crystal display device, which includes a backlight module and a liquid crystal display panel arranged on the light-emitting side of the backlight module. The display substrate can be used as an array substrate of the liquid crystal display panel.

Evidently those skilled in the art can make various modifications and variations to the present disclosure without departing from the spirit and scope of the present disclosure. Thus the present disclosure is also intended to encompass these modifications and variations therein as long as these modifications and variations to the present disclosure come into the scope of the claims of the present disclosure and their equivalents.

1. A display substrate, comprising:
a base substrate comprising a plurality of sub-pixel regions, each of the plurality of sub-pixel regions comprising a reflective region and a transmissive region;
a plurality of pixel driving units, arranged on a side of the base substrate, wherein orthographic projections of the plurality of pixel driving units on the base substrate are located in the plurality of sub-pixel regions in a one-to-one correspondence;
wherein each of the plurality of pixel driving units comprises:
a driving circuit layer, arranged on the base substrate and comprising a transistor driving circuit;
an organic layer, arranged on a side of the driving circuit layer facing away from the base substrate, wherein the organic layer is provided with a first connection hole, an orthographic projection of the first connection hole on the base substrate at least partially overlaps with the transmissive region;
a reflective electrode, arranged on a side of the organic layer facing away from the driving circuit layer, wherein an orthographic projection of the reflective electrode on the base substrate at least covers the reflective region, the reflective electrode is provided with a first light-transmitting hole corresponding to the first connection hole, an orthographic projection of the first light-transmitting hole on the base substrate coincides with the transmissive region.

2. The display substrate according to claim 1, wherein the pixel driving unit further comprises an inorganic layer and a connection wire; wherein:
the inorganic layer is arranged between the organic layer and the driving circuit layer, the inorganic layer is provided with a second connection hole, and an orthographic projection of the second connection hole on the base substrate at least partially overlaps with the orthographic projection of the first connection hole on the base substrate;
the connection wire is arranged between the inorganic layer and the base substrate, a first end of the connection wire is electrically connected to the transistor driving circuit, a second end of the connection wire is exposed from the second connection hole and electrically connected to the reflective electrode.

3. The display substrate according to claim 2, wherein the second end of the connection wire is exposed from the first connection hole; and the reflective electrode is connected to the second end of the connection wire in the first connection hole.

4. The display substrate according to claim 2, wherein the pixel driving unit further comprises: a transparent electrode arranged between the driving circuit layer and the reflective electrode;
an orthographic projection of the transparent electrode on the base substrate at least covers the orthographic projection of the first connection hole on the base substrate;
the reflective electrode is connected to the second end of the connection wire through the transparent electrode.

5. The display substrate according to claim 4, wherein the transparent electrode is arranged between the organic layer and the reflective electrode.

6. The display substrate according to claim 3, wherein an orthographic projection of the connection wire on the base substrate overlaps with an edge of the orthographic projection of the first connection hole on the base substrate.

7. The display substrate according to claim 6, wherein, in a radial direction of the first connection hole, only one side of the orthographic projection of the first connection hole on the base substrate overlaps with the orthographic projection of the connection wire on the base substrate.

8. The display substrate according to claim 6, wherein, in a radial direction of the first connection hole, a width of an overlapping region between the orthographic projection of the first connection hole on the base substrate and the orthographic projection of the connection wire on the base substrate is greater than 0 microns and less than or equal to 3 microns.

9. The display substrate according to claim 6, wherein the pixel driving unit further comprises a transparent electrode, a region of the transparent electrode corresponding to the first connection hole is recessed into the first connection hole to form a concave portion;
the orthographic projection of the first light-transmitting hole on the base substrate coincides with an orthographic projection of the concave portion on the base substrate.

10. The display substrate according to claim 1, wherein the pixel driving unit further comprises an inorganic layer and a transparent electrode; wherein:
the inorganic layer is arranged between the organic layer and the driving circuit layer, the inorganic layer is provided with a third connection hole, and an orthographic projection of the third connection hole on the base substrate does not overlap with the orthographic projection of the first connection hole on the base substrate;
the transparent electrode is arranged between the inorganic layer and the organic layer, the transparent electrode is electrically connected to the transistor driving circuit through the third connection hole, and the transparent electrode is electrically connected to the reflective electrode through the first connection hole.

11. The display substrate according to claim 10, wherein the driving circuit layer is provided with a second light-transmitting hole, the inorganic layer is provided with a third light-transmitting hole;
an orthographic projection of the second light-transmitting hole on the base substrate covers an orthographic projection of the third light-transmitting hole on the base substrate;
the orthographic projection of the third light-transmitting hole on the base substrate covers the orthographic projection of the first light-transmitting hole on the base substrate;
a region of the transparent electrode corresponding to the third light-transmitting hole is recessed into the second light-transmitting hole and the third light-transmitting hole; and
the reflective electrode is electrically connected to the transparent electrode through the first connection hole.

12. The display substrate according to claim 1, wherein the driving circuit layer comprises a gate metal layer, a gate insulating layer, a semiconductor layer, and a source-drain metal layer sequentially arranged on the base substrate;
the transistor driving circuit comprises: a switching transistor and a capacitor electrode;
the switching transistor comprises: a gate electrode arranged in the gate metal layer, an active layer arranged in the semiconductor layer, and a first electrode and a second electrode arranged in the source-drain metal layer;
the first electrode and the second electrode are electrically connected to the active layer, the first electrode is electrically connected to the reflective electrode, and the capacitor electrode is arranged between the source-drain metal layer and the base substrate, and the capacitor electrode is arranged opposite to the first electrode.

13. The display substrate according to claim 12, wherein the driving circuit layer further comprises a pad layer on a same layer as the gate electrode;
wherein the pad layer is provided with a fourth light-transmitting hole, and an orthographic projection of the fourth light-transmitting hole on the base substrate covers the orthographic projection of the first connection hole on the base substrate.

14. The display substrate according to claim 1, wherein the organic layer is provided with a scattering portion on a side facing the reflective electrode; and
an orthographic projection of the scattering portion on the base substrate covers the reflective region.

15. The display substrate according to claim 1, wherein the orthographic projection of the reflective electrode on the base substrate covers an orthographic projection of the transistor driving circuit on the base substrate.

16. A display device, comprising the display substrate according to claim 1.

17. The display device according to claim 16, wherein the pixel driving unit further comprises an inorganic layer and a connection wire; wherein:
the inorganic layer is arranged between the organic layer and the driving circuit layer, the inorganic layer is provided with a second connection hole, and an orthographic projection of the second connection hole on the base substrate at least partially overlaps with the orthographic projection of the first connection hole on the base substrate;
the connection wire is arranged between the inorganic layer and the base substrate, a first end of the connection wire is electrically connected to the transistor driving circuit, a second end of the connection wire is exposed from the second connection hole and electrically connected to the reflective electrode.

18. The display device according to claim 17, wherein the second end of the connection wire is exposed from the first connection hole; and the reflective electrode is connected to the second end of the connection wire in the first connection hole.

19. The display device according to claim 17, wherein the pixel driving unit further comprises: a transparent electrode arranged between the driving circuit layer and the reflective electrode;
an orthographic projection of the transparent electrode on the base substrate at least covers the orthographic projection of the first connection hole on the base substrate;
the reflective electrode is connected to the second end of the connection wire through the transparent electrode.

20. The display device according to claim 19, wherein the transparent electrode is arranged between the organic layer and the reflective electrode.
